(19) United States
(12) Patent Application Publication
(10) Pub. No.: US 2002/0011615 A1
(43) Pub. Date: Jan. 31, 2002

(54) FERROELECTRIC MEMORY DEVICE AND METHOD FOR PRODUCING THE SAME

(76) Inventors: MASAYA NAGATA, NARA-SHI (JP); JUN KUDO, NARA-SHI (JP)

Correspondence Address: NIXON & VADERHYE P C, ATTY H WARREN BURNAM JR, 1100 N GLEBE ROAD, 8TH FLOOR, ARLINGTON, VA, 22201

(21) Appl. No.: 09/357,806

(22) Filed: Jul. 20, 1999

(30) Foreign Application Priority Data
Jul. 24, 1998 (JP) 10-210135

(51) Int. Cl. H01L 31/119; H01L 31/113; H01L 29/94; H01L 29/76

(52) U.S. Cl. 257/295

(57) ABSTRACT

A ferroelectric memory device includes: a capacitor having an upper electrode, a ferroelectric film, and a lower electrode; a conductive plug disposed under the lower electrode for electrically connecting the lower electrode to a selection transistor; and a diffusion barrier film formed between the conductive plug and the lower electrode for preventing a diffusion reaction between the conductive plug and the lower electrode. A silicide layer is formed between the conductive plug and the diffusion barrier film, the silicide layer comprising a first metal element.

### BACKGROUND OF THE INVENTION

1. Field of the Invention

The present invention relates to a ferroelectric memory device and a method for producing the same. In particular, the present invention relates to a ferroelectric memory device including a selection transistor, a capacitor having upper and lower electrodes and a ferroelectric film, and a conductive plug for electrically interconnecting the selection transistor and the capacitor, as well as a method for producing the same.

2. Description of the Related Art

Ferroelectric materials are utilized as component elements in various devices in a wide range of fields because these materials provide many functions, e.g., spontaneous polarization, high dielectric constant, electrooptical effects, piezoelectric effects, and pyroelectric effects. For example, the pyroelectric properties of ferroelectric materials are utilized in infrared linear array sensor applications; their piezoelectric properties are utilized in ultrasonic wave sensor applications; their electrooptical effects are utilized in waveguide type optical modifier applications; their ferroelectric properties are utilized in capacitors for use in DRAMs (dynamic random-access memories) and MMICs (microwave monolithic integrated circuits), and so on. Above all, the recent development in thin film formation technologies, taken in conjunction with semiconductor memory technologies, has led to vigorous research and development activities for non-volatile memories (FRAMs: ferroelectric random access memories) which are capable of high-density implementation and high-speed operation.

FRAMs provide advantages such as high-speed writing/reading, low voltage operation, and high endurance through repetitive writing/reading. Therefore, research and development efforts have been made to implement FRAMs which can replace not only conventional EPROMs (erasable and programmable read only memories) and EEPROMs (electrically erasable and programmable read only memories), and flash memories, but potentially SRAMs (static random access memories) and/or DRAMs also.

Conventionally, oxide ferroelectric materials, e.g., Pb(Zr₁₋ₓTiₓ)O₃, SrBi₂Ta₂O₉, Bi₄Ti₃O₁₂, etc.) have been studied as ferroelectric materials for use in ferroelectric capacitors in FRAMs. Among others, SrBi₂Ta₂O₉ is the most suitable material for FRAMs because it is capable of low-voltage operation at 3 V or less, and has excellent reliability (e.g., fatigue characteristics, imprint characteristics, temperature characteristics, and the like) to ensure stable operation of a ferroelectric memory. As a lower electrode of such a ferroelectric capacitor, electrodes formed of a precious metal material (e.g., Pt, Pt/Ta, Pt/Ti), or complex electrodes composed of a precious metal material layer and a closely contacting film, have been used to study the characteristics of thin ferroelectric films.

A ferroelectric film must be subjected to a high-temperature heat treatment at about 650° C. to about 800° C. in an oxygen atmosphere for imparting the film with satisfactory ferroelectric characteristics. On the other hand, it is generally essential to employ a stacked structure in order to achieve a high density integration, e.g. , 1 Mbit or above, by utilizing such a ferroelectric capacitor and ferroelectric-capacitor manufacturing processes.

FIG. 1 illustrates the structure of a conventional ferroelectric memory device having a stacked structure. In this structure, a selection transistor 20 and a ferroelectric capacitor 40 are electrically interconnected via a conductive plug 30 (of polysilicon or the like)., The selection transistor 20 includes a gate electrode 22 formed on a silicon substrate 10, and source/drain regions 24a and 24b interposing the gate electrode 22. The conductive plug 30 is buried in a through hole in a first interlayer insulation film 52. The ferroelectric capacitor 40 includes a lower electrode 44 which is directly coupled to the conductive plug 30, a thin ferroelectric film 46, and an upper electrode 48. Furthermore, a second interlayer insulation film 54 is formed on the ferroelectric capacitor 40 and the first interlayer insulation film 52. The upper electrode 48 is coupled to a take-out electrode 62 via a contact hole in the overlying second interlayer insulation film 54. The source region 24a of the selection transistor 20 is coupled to a take-out electrode 64 via a contact hole in the first and second interlayer insulation films 52 and 54. A LOCOS film 51 is provided as a device separation region.

In the above-described stacked structure, the lower electrode 44 (of Pt or the like ) is formed directly on the conductive plug 30 (which is made of polysilicon). Therefore, a silicidation reaction may occur between Pt and polysilicon during a heat treatment in the ferroelectric capacitor processing, thereby deteriorating the ferroelectric characteristics.

Conventionally, a diffusion barrier film (e.g., TiN) is employed between the lower electrode 44 and the polysilicon (conductive plug) 30, so as to prevent the aforementioned silicidation reaction. However, the TiN layer in the Pt/TiN structure may be oxidized by gaseous oxygen which has permeated the Pt film grain boundaries during the crystallization heat treatment process for the ferroelectric material, as reported in “Proceedings of 43rd Applied Physics Association Lecture Meeting, 1996 Spring, 28p-V-6 (p. 500)”. Furthermore, as reported in “Proceedings of 43rd Applied Physics Association Lecture Meeting, 1996 Spring, 28p-V-7 (p. 500)”, oxidation of TiN, if it occurs, may cause peeling at the Pt/TiN interface or an upward formation of Pt hillocks due to stress associated with the volume expansion resulting from the oxidation of TiN. This presents a considerable problem.

In the case of a Pt/polysilicon structure or a Pt/TiN/polysilicon structure, the electrical contact between the lower electrode and the polysilicon may become insufficient due to Pt silicidation or TiN oxidation resulting in hillocks or the like. Thus, it has been difficult to realize a stacked structure.

On the other hand, the use of not only Pt but also Ir, PtRh, Ru or oxides thereof (e.g., IrO₂, PtRhOₓ, or RuO₂) for a lower electrode has begun to be studied because of their excellent barrier properties and excellent matching with any overlying oxide dielectric material. Among others, the use of Ir and IrO₂ can greatly improve the fatigue characteristics of PZT formed upon an Ir/IrO₂/polysilicon electrode structure or a Pt/lrO₂/polysilicon electrode structure, as reported in Appl. Phys. Lett., vol. 65 (1994), pp. 1522-1524 and Jpn. J. Appl. Phys., vol. 33 (1994), pp. 5207-5210. Such improvement is ascribed to the barrier properties of the IrO₂ film against the elements (e.g., Pb) composing the ferroelectric film.

However again, such a structure is susceptible to the problem of insufficient contact due to oxidation of the polysilicon at the IrO₂/polysilicon interface during the IrO₂ film formation and the ferroelectric film formation.

An IrO₂/Ir/TiN/Ti lower electrode, incorporating a TiN film as a barrier metal for an oxide electrode (IrO₂), has been reported in “Proceedings of 43rd Applied Physics Association Lecture Meeting, 1996 Spring, 28p-V-4 (p. 499)” as a solution to the problem associated with reactions between Ir or IrO₂ and polysilicon. The report describes that a ferroelectric SrTiO₃ film was actually produced, and in accordance with this structure, ohmic contact was realized between the ferroelectric SrTiO₃ film and a silicon substrate whose resistance had been lowered by ion injection, and that ferroelectric characteristics similar to those of Pt were obtained.

In the case of employing a relatively low temperature process in the range of about 200° C. to about 450° C. (which is applicable to ferroelectric materials such as SrTiO₃), an lrO₂/Ir/TiN/Ti lower electrode structure might seem as promising for realizing a stacked structure incorporating a ferroelectric capacitor, because deterioration in the electric characteristics of the capacitor due to hillock generation or reduced flatness does not occur.

However, in the case of ferroelectric materials such as PZT, a ferroelectric crystallization process in an oxygen atmosphere at about 600° C. or more is required. For SrBi₂Ta₂O₉, a high temperature heat treatment in the range of about 650° C. to about 800° C. is required. At such a high temperature, the use of a Pt/TiN lower electrode structure may result in the generation of Pt hillocks due to changes in the film stress caused by TiN oxidation.

### SUMMARY OF THE INVENTION

A ferroelectric memory device according to the present invention includes: a capacitor having an upper electrode, a ferroelectric film, and a lower electrode; a conductive plug disposed under the lower electrode for electrically connecting the lower electrode to a selection transistor; and a diffusion fusion barrier film formed between the conductive plug and the lower electrode for or preventing a diffusion reaction between the conductive plug and the lower electrode, wherein a silicide layer is formed between the conductive plug and the diffusion barrier film, the silicide layer containing a first metal element.

In one embodiment of the invention, the first metal element is selected from IV-A group elements (Ti, Zr, and Hf), V-A group elements (V, Nb, and Ta), VI-A group elements (Cr, Mo, and W), and VIII group elements (Ru, Os, Co, Rh, Ir, Ni, Pd and Pt).

In another embodiment of the invention, the diffusion barrier film is composed essentially of one of AₓSi₁₋ₓN_{y}, AₓAl₁₋ₓN_{y}, and BN_{z} (where 0.2≦x≦1; 0≦y≦1; 0 ≦z≦1), wherein A is an element which is selected from a group including Ti, Zr, Hf, V, Nb, Ta, Cr, Mo, W, Ru, Os, Co, Rh, Ir, Ni, Pd, and Pt; and B is an element which is selected from a group including Zr, Hf, V, Nb, Ta, Cr, Mo, W, Ru, Os, Co, Rh, Ir, Ni, Pd, and Pt.

In still another embodiment of the invention, the lower electrode is composed essentially of at least one of an Ir film and a multilayer film including an Ir layer and an IrO₂ layer.

In still another embodiment of the invention, the silicide layer has a thickness of about 2 to about 60 nm.

In still another embodiment of the invention, the conductive plug is composed essentially of polysilicon.

A method for producing a ferroelectric memory device including a capacitor having an upper electrode, a ferroelectric film, and a lower electrode; a conductive plug disposed under the lower electrode for electrically coupling the lower electrode to a selection transistor; and a diffusion barrier film formed between the conductive plug and the lower electrode for preventing a diffusion reaction between the conductive plug and the lower electrode includes a step of forming a silicide layer between the conductive plug and the diffusion barrier film, the silicide layer contains a first metal element.

In one embodiment of the invention, the first metal element is selected from IV-A group elements (Ti, Zr, and Hf), V-A group elements (V, Nb, and Ta), VI-A group elements (Cr, Mo, and W), and VIII group elements (Ru, Os, Co, Rh, Ir, Ni, Pd and Pt).

In another embodiment of the invention, the conductive plug is composed essentially of silicon, and the step of forming the silicide layer includes: forming a metal layer on the conductive plug, the metal layer containing the first metal element; and performing a heat treatment in an inert gas atmosphere to convert the metal layer into the silicide layer.

In still another embodiment of the invention, the step of forming the silicide layer includes: forming a first layer on the conductive plug, the first layer containing the first metal element and Si; and performing a heat treatment in an inert gas atmosphere to convert the first layer into the silicide layer.

In still another embodiment of the invention, the conductive plug is composed essentially of silicon, and the step of forming the silicide layer includes: forming a metal layer on the conductive plug, the metal layer on the metal layer, the first layer containing the first metal element and Si; and performing a heat treatment in an inert gas atmosphere to convert the metal layer and the first layer into the silicide layer.

In still another embodiment of the invention, the conductive plug is composed essentially of silicon, and the step of forming the suicide layer includes: forming a first metal layer on the conductive plug, the first metal layer containing the first metal element; performing a heat treatment in an inert gas atmosphere to convert the first metal layer into the silicide layer; and forming a second metal layer on the silicide layer, the second metal layer containing the first metal element.

In still another embodiment of the invention, the inert gas is composed essentially of nitrogen gas.

In still another embodiment of the invention, the heat treatment is performed before ore forming the diffusion barrier film, the heat treatment being performed at a temperature ranging from about 500° C. to about 950° C.

In still another embodiment of the invention, the heat treatment is performed after forming the diffusion barrier film, the heat treatment being performed at a temperature ranging from about 500° C. to about 800° C.

In still another embodiment of the invention, the diffusion barrier film is composed essentially of one of AₓSi₁₋ₓN_{y}, AₓAl₁₋ₓN_{y}, and BN₂ (where 0.2≦x≦1; 0≦y≦1; 0 ≦z<1), wherein A is an element which is selected from a group including Ti, Zr, Hf, V, Nb, Ta, Cr, Mo, W, Ru, Os, Co, Rh, Ir, Ni, Pd, and Pt; and B is an element which is selected from a group including Zr, Hf, V, Nb, Ta, Cr, Mo, W, Ru, Os, Co, Rh, Ir, Ni, Pd, and Pt.

Thus, the invention described herein makes possible the advantages of (1) providing a ferroelectric memory device of a stacked structure including a lower electrode structure which has high resistance against a heat treatment conducted in an oxygen atmosphere at about 600° C. or more and exhibits excellent contact characteristics with respect to a conductive plug; and (2) providing a method for producing the same.

These and other advantages of the present invention will become apparent to those skilled in the art upon reading and understanding the following detailed description with reference to the accompanying figures.

### BRIEF DESCRIPTION OF THE DRAWINGS

FIG. 1 is a cross-sectional view illustrating a conventional ferroelectric memory device.

FIG. 2 is a cross-sectional view illustrating a ferroelectric memory device according to the present invention.

FIGS. 3A to 3D are cross-sectional views illustrating respective steps of a method for producing a ferroelectric memory device according to the present invention.

FIG. 4 is a hysteresis diagram of a ferroelectric material.

FIGS. 5A to 5H are cross-sectional views (5A to 5G) and a plan view (5H) illustrating a process for preparing a Kelvin pattern.

FIG. 6 is a graph illustrating the contact diameter dependency of contact resistance, measured by a four-terminal method using a Kelvin pattern.

FIG. 7A is a graph illustrating current-voltage characteristics when measuring contact resistance according to the present invention.

FIG. 7B is a graph illustrating current-voltage characteristics when measuring contact resistance under the prior art.

FIG. 8 is a graph illustrating the distributions of respective component elements of a ferroelectric capacitor, taken along the direction of the depth of the thin ferroelectric film.

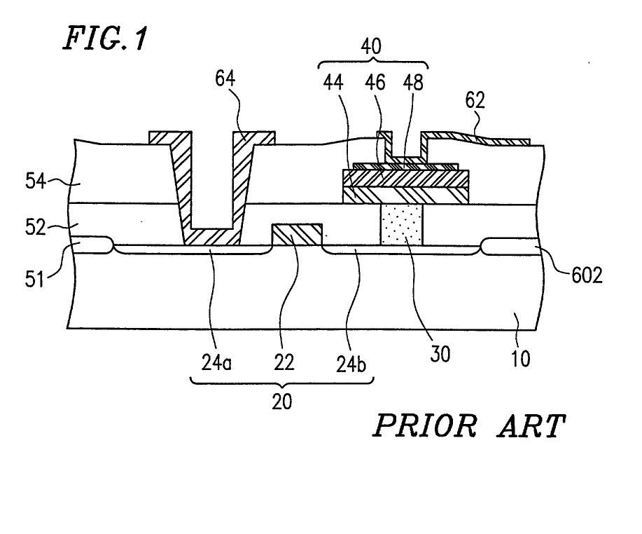

### DESCRIPTION OF THE PREFERRED EMBODIMENTS

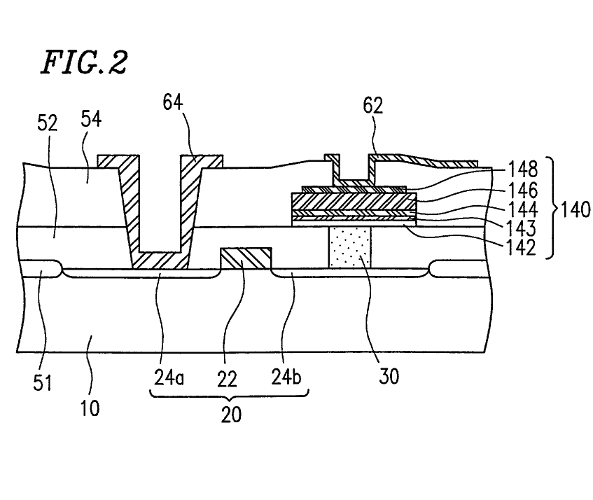

Hereinafter, fundamental features of the present invention will be described with reference to FIG. 2.

FIG. 2 is a cross-sectional view illustrating an essential portion of the fundamental structure of a ferroelectric memory device according to the present invention. The ferroelectric memory device includes a selection transistor 20 formed on a substrate 10, a ferroelectric capacitor 140 formed on the selection transistor 20 with a first interlayer insulation film 52 interposed therebetween, and a conductive plug 30 buried in a contact hole through the first interlayer insulation film 52. The conductive plug 30, which is formed of polysilicon or the like, electrically interconnects the selection transistor 20 and the ferroelectric capacitor 140.

The ferroelectric capacitor 140 includes a lower electrode 144, a thin ferroelectric film 146, and an upper electrode 148. The lower electrode 144 of the ferroelectric capacitor 140 according to the present invention is formed of Ir or IrO₂.

The ferroelectric capacitor 140 further includes a diffusion barrier film 143 and an underlying silicide layer 142 provided between the lower electrode 144 and the conductive plug 30. The silicide layer 142 contains a first metal, which is defined as an element selected from IV-A group elements (Ti, Zr, and Hf), V-A group elements (V, Nb, and Ta), VI-A group elements (Cr, Mo, and W), and VIII group elements (Ru, Os, Co, Rh, Ir, Ni, Pd and Pt).

The diffusion barrier film 143, which is formed of AₓSi₁₋ₓN_{y}, AₓAl₁₋ₓN_{y}, or BN_{z} (where 0.2≦x<1; 0≦y≦1; 0 ≦z<1), prevents the diffusion reaction between the conductive plug 30 and the lower electrode 144. In the above chemical formulae, A is an element which is selected from Ti, Zr, Hf, V, Nb, Ta, Cr, Mo, W, Ru, Os, Co, Rh, Ir, Ni, Pd, and Pt; and B is an element which is selected from Zr, Hf, V, Nb, Ta, Cr, Mo, W, Ru, Os, Co, Rh, Ir, Ni, Pd, and Pt.

Hereinafter, effects which are attained by the above structure will be described.

The lower electrode 144, which is formed of an Ir or IrO₂/Ir film, prevents oxygen from being diffused into the diffusion barrier film 143 (which in itself is formed of, e.g., a TaₓSi₁₋ₓN_{y} film; hereinafter such a film will be referred to also as a “TaSiN film”) due to the high temperature at which a crystallization process is performed for the overlying ferroelectric film. As a result, the volume expansion of the TaₓSi₁₋ₓN_{y} film and/or contact insufficiency due to oxidation can be prevented. The use of a lower electrode of an Ir or IrO₂ film, and the use of the aforementioned diffusion barrier film are partially described in Japanese Application No. 10-035639 (entitled “SEMICONDUCTOR MEMORY DEVICES AND METHOD FOR PRODUCING THE SAME), too.

The diffusion barrier film 143 (e.g., TaₓSi₁₋ₓN_{y} film) functions as a diffusion barrier between the silicide layer 142 (e.g., titanium silicide) and the Ir or IrO₂/Ir film formed on the TaₓSi₁₋ₓN_{y} film. The TaₓSi₁₋ₓN_{y} film 143 prevents elements such as silicon or Ti, from diffusing into the lower electrode 144.

The use of the diffusion barrier film 143 and the lower electrode 144 as described above prevents the formation of hillocks, on the lower electrode 144 or between the lower electrode 144 and the diffusion barrier film 143, during a ferroelectric crystallization process at about 700° C. for about 60 minutes. As a result, a ferroelectric memory device including a ferroelectric film having excellent ferroelectric characteristics can be provided.

Hereinafter, the significance of providing the silicide film 142 according to the present invention will be described.

It has been found through a detailed interfacial analysis by the inventors that if the TaₓSi₁₋ₓN_{y} diffusion barrier film 143 is directly formed on polysilicon, a very thin reaction layer is formed at the interface between the TaₓSi₁₋ₓN_{y} film and the polysilicon. Such a reaction layer, if formed, may increase the contact resistance between the lower electrode 144 and the conductive plug 30 after performing a ferroelectric crystallization process, possibly resulting in non-ohmic current-voltage characteristics. Such non-ohmic current-voltage characteristics are likely to cause problems such as unwanted delay during a high-speed operation and/or poor S/N ratios in the ferroelectric memory operation.

The generation of such a reaction layer can be prevented by providing a silicide layer. Furthermore, due to the presence of a silicide layer, the contact strength between the polysilicon and the TaₓSi₁₋ₓN_{y} diffusion barrier film 143 is improved, thereby contributing to the reduction of hillocks. In accordance with this structure, problems such as peeling of the TaₓSi₁₋ₓN_{y} diffusion barrier film 143 and hillock formation can be prevented even by performing a heat treatment at about 700° C. or more for 240 minutes, and yet excellent contact characteristics are attained between the lower electrode and the polysilicon plug 30.

Hereinafter, the other constituent elements shown in FIG. 2 are described. It is commonplace to employ an oxide ferroelectric material, e.g., (lead-zirconate-titanate; PZT), SrBi₂Ta₂O₉ (SBT) or Bi₄Ti₃O₁₂ for the thin ferroelectric film 146 overlying the lower electrode 144. In the case of an SBT material, any Bi type ferroelectric material having a laminar perovskite structure can be used, but especially preferable materials in this category include Bi₂Aₘ₋₁B₃ₘ₊₃ (where A represents Na, K, Pb, Ca, Sr, Ba or Bi; and B represents Fe, Ti, Nb, Ta, W, or Mo); it is even more preferable if m is a natural number. Examples of such preferable materials include Bi₄Ti₃O₁₂, SrBi₂(Taₓ, Nb₁₋ₓ)₂O₉ (where 0≦x<1), BaBi₂Nb₂O₉, BaBi₂Ta₂O₉, PbBi₂Ta₂O₉, PbBi₂Nb₂O₉, PbBi₄Ti₃O₁₅, SrBi₄Ti₄O₁₅, BaBi₄Ti₄O₁₅, Sr₂Bi₄Ti₅O₁₈, Ba₂Bi₄Ti₅O₁₈, Pb₂Bi₄Ti₅O₁₈, Na_{0.5}Bi_{4.5}Ti₄O₁₅, K_{0.5}Bi_{4.5}Ti₄O₁₅, and the like. Alternatively, solid solutions such as SrBi₂(Taₓ, Nb₁₋ₓ)₂O₉ (where 0≦x<1) and SrBi₂(Taₓ, Nb₁₋ₓ)₂O₉)_{0.7} • (Bi₃TiTaO₉)_{0.3} (where 0≦x<1) can also be used.

Such a ferroelectric film can be formed by a known method, e.g., a spin-on method, a reactive vapor deposition method, an electron beam (EB) vapor deposition method, a sputtering method, a laser ablation method, or a metal-organic chemical vapor deposition (MOCVD) method. For example, a spin-on method can be performed as follows. All or some elements which compose the thin ferroelectric film 146 are dispersed in a solvent and applied on a substrate by spin coating, and dried. Next, carbon components which are present in the film are burnt through sintering (preliminary sintering). Thereafter, the resultant composite is subjected to sintering in a gas containing oxygen or an oxygen compound so as to be converted into a crystal having a perovskite structure. As a result, the ferroelectric film 146 is formed on the substrate.

The upper electrode 148 provided on the ferroelectric film 146 can be formed so as to have a single layer film structure of Pt or the like, or alternatively formed from a material similar to the material of the lower electrode 144 by using a similar method.

The selection transistor 20 has a gate electrode 22 and source/drain regions 24a and 24b formed on the silicon substrate 10, the source/drain regions 24a and 24b interposing the gate electrode 22. In the structure shown in FIG. 2, a second interlayer insulation film 54 is formed on the ferroelectric capacitor 140 and the first interlayer insulation film 52. The upper electrode 148 is coupled to a take-out electrode 62 via a contact hole in the overlying second interlayer insulation film 54. The source region 24a of the selection transistor 20 is coupled to a take-out electrode 64 via a contact hole in the first and second interlayer insulation films 52 and 54. A LOCOS film 51 is provided as a device separation region.

Any substrate that can be used as a substrate for usual semiconductor devices or integrated circuits can be used as the substrate of the ferroelectric memory device according to the present invention, but a silicon substrate is preferable.

The ferroelectric memory device according to the present invention incorporating a ferroelectric material can be mounted on a wafer for use in integrated circuits in such a manner that the incorporated ferroelectric material serves as a component element of a given ferroelectric device or semiconductor device of an integrated circuit. For example, the ferroelectric element can be utilized as a capacitor section of a non-volatile memory or a gate electrode of an FET. With the addition of a gate insulation film, source/drain regions and the like, MFMIS-FETs (metal ferroelectric metal insulator semiconductor FETs), MFS-FETs (metal ferroelectric semiconductor FETs), and the like can be conveniently realized.

Hereinafter, the present invention will be described by way of examples, with particular reference to a method for forming a silicide layer.

### EXAMPLE 1

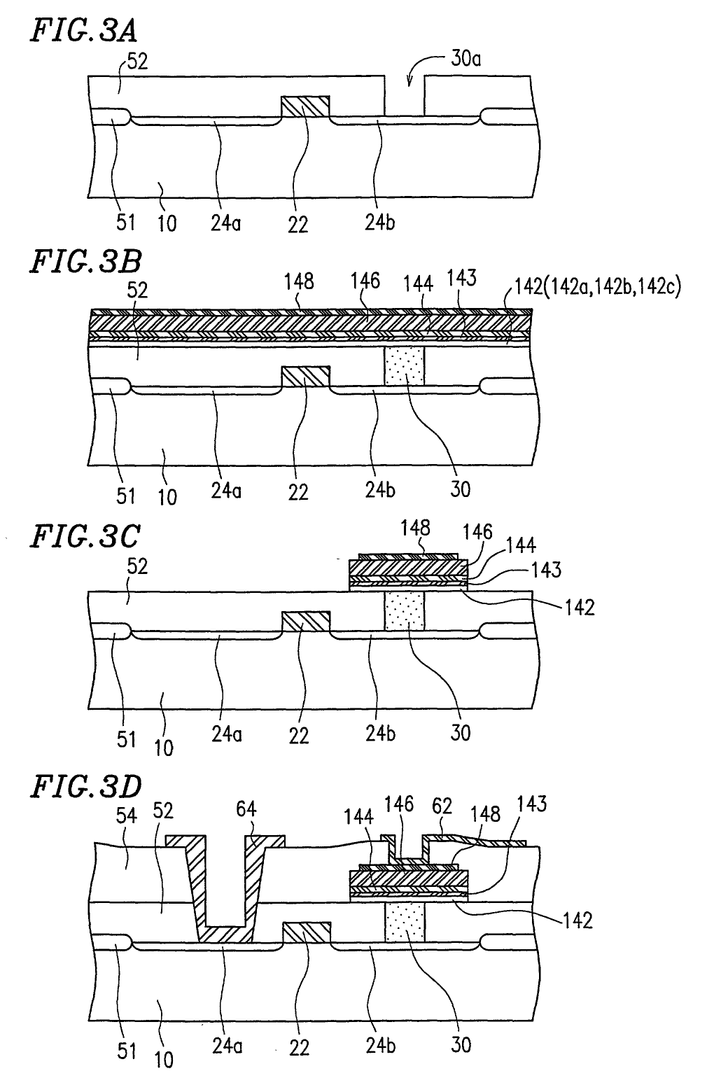

With reference to FIGS. 3A to 3D, a method for producing a ferroelectric memory device according to Example 1 of the present invention will be described. In the present example, a metal film (Ti film) formed on a polysilicon conductive plug is subjected to a heat treatment, thereby forming a silicide layer.

First, as shown in FIG. 3A, a LOCOS (local oxidation of silicon) film 51 (thickness: about 50 nm) is formed on the surface of a silicon substrate 10 so as to form a device separation region. Then, by using a known method, a selection transistor is formed having a gate electrode 22, source/drain regions 24a and 24b. Thereafter, a first silicon oxide film 52 is formed as an interlayer insulation film with a thickness of about 500 nm by a vapor deposition (CVD) method. Then, a contact hole 30a having a diameter of about 0.6 μm is formed.

Next, as shown in FIG. 3B, polysilicon is buried in the contact hole 30a by CVD, and thereafter the surface of the polysilicon is flattened by a chemical mechanical polishing (CMP) method, thereby forming the polysilicon conductive plug 30. Next, the surface of the polysilicon is subjected to a wet process with hydrofluoric acid in order to prevent any spontaneous oxidation films from being formed on the polysilicon, as a pretreatment before forming a Ti film on the polysilicon conductive plug 30.

Thereafter, a Ti film 142a is formed on the polysilicon conductive plug 30 and the first silicon oxide film 52 by DC magnetron sputtering so as to have a thickness of about 1 to about 30 nm (preferably about 5 nm to about 25 nm). If the thickness of the Ti film 142a is less than about 1 nm, it becomes difficult to obtain satisfactory contact resistance. If the thickness of the Ti film 142a exceeds about 30 nm, the Ti film surface may become coarse after performing an annealing for ferroelectric crystallization.

Thereafter, a TaₓSi₁₋ₓN_{y} diffusion barrier film 143 (where 0.2≦x≦1 and 0≦y≦1) is formed on the Ti film 142a so as to have a thickness of about 50 to about 150 nm (preferably about 80 to about 120 nm) by a DC reactive magnetron sputtering method. If the thickness of the diffusion barrier film 143 is less than about 50 nm, it becomes difficult for the diffusion barrier film 143 to function as a diffusion barrier layer. If the thickness of the diffusion barrier film 143 exceeds about 150 nm, the film thickness of the entire capacitor portion is increased, leading to a poorer fine processing accuracy. The film formation conditions for forming the TaₓSi₁₋ₓN_{y} film 143 according to the present example are as follows: a target whose Ta/Si molar ratio is about 10/3 is used; the substrate temperature is about 500° C.; a sputter power of about 2 kW is used; a sputter gas pressure of about 0.7 Pa is used; and an Ar/N₂ flow ratio of about 3/2 is used.

After the TaₓSi₁₋ₓN_{y} film 143 is formed, a heat treatment is conducted in a pure nitrogen atmosphere at about 500° C. to about 800° C. (preferably about 600° C.) for 1 hour, as a result of which the Ti film 142 reacts with the polysilicon to form the silicide layer 142 (thickness: about 2 to about 60 nm). If the treatment temperature is about 500° C. or less, it becomes difficult to ensure sufficient formation of silicide. If the heat treatment temperature exceeds about 800° C., the reaction between the Ti film and the polysilicon may proceed too far during the 1-hour heat treatment, thereby resulting in a somewhat rough silicide surface. Furthermore, if the heat treatment temperature exceeds about 800° C., the TaₓSi₁₋ₓN_{y} film 143 may itself be unfavorably affected. Instead of pure nitrogen, the heat treatment can employ any other inert gas, e.g., Ar, Kr, or He for similar effects.

An X-ray diffraction analysis was performed to confirm that The TaₓSi₁₋ₓN_{y} diffusion barrier film 143 had an amorphous structure. Furthermore, the composition of the TaₓSi₁₋ₓN_{y} was confirmed to be Ta_{0.85}Si_{0.15}N_{0.41} through an Auger electron spectroscopy. The resistivity of the TaₓSi₁₋ₓN_{y} film 143 after a heat treatment in a pure nitrogen atmosphere was measured to be in the range of about 100 to about 2000 μΩ cm. If the value of x in TaₓSi₁₋ₓN_{y} is smaller than about 0.2, the Si component becomes excessive, resulting in an extremely high resistivity which is not suitable for the device. Accordingly, the range between about 0.2≦x≦ about 1 is considered suitable.

Thereafter, an Ir lower electrode film 144 is formed on the diffusion barrier film 143 so as to have a thickness of about 50 to about 300 nm (preferably about 100 to about 200 nm) by a DC magnetron sputtering method. If the thickness of the Ir film 144 is less than about 50 nm, the oxygen in the atmosphere may permeate the Ir film 144 during the annealing for ferroelectric crystallization, thereby allowing hillocks to be formed due to volumetric expansion of the TaₓSi₁₋ₓN_{y} film 143. If the thickness of the Ir film 144 exceeds about 300 nm, the thickness of the entire capacitor portion is increased, thereby resulting in a poorer fine processing accuracy and/or difficulty to perform processing with a conventional resist film thickness. The film formation conditions for forming the Ir film 144 according to the present example are as follows: a DC power of about 0.5 kW a substrate temperature of about 500° C.; and a gas pressure of about 0.6 Pa.

Next, an SrBi₂Ta₂O₉(SBT) film 146 is formed on the Ir film 144 by a spin-on method. Specifically, the SBT film can be formed as follows: First, a precursor solution is prepared which contains elements for composing the SBT dispersed in a solvent. The precursor solution is applied on a substrate by using a spinner whose rotation rate is set at about 3000 rpm; then the SBT film is dried at about 150° C. in the atmosphere for about 10 minutes; then the SBT film is subjected to a preliminary sintering in the atmosphere at about 400° C. for about 30 minutes; then a crystallization process is performed at about 675° C. for about 60 minutes. After repeating these steps four times, the SBT film has a thickness of about 120 nm. The resultant SBT film does not include hillocks and does not present peeling problems. As a result of a cross-sectional SEM (scanning electron microscopy) observation, it was confirmed that no reaction occurred in the respective layers.

Next, a Pt upper electrode 148 is formed on the SBT film 146 so as to have a thickness of about 100 nm by a DC magnetron sputtering method.

Thereafter, as shown in FIG. 3C, the upper electrode 148 is patterned into areas having a size of about 1 μm×1 μm to about 3 μm×3 μm by a dry etching using Cl₂. The underlying SBT film 146 is patterned into a predetermined shape by a dry etching using C₂F₆ and Ar. Then, the Ir lower electrode 144, the TaₓSi₁₋ₓN_{y} diffusion barrier film 143, and the silicide layer 142 are processed so as to have a predetermined shape by a dry etching using Cl₂ and C₂F₆.

Thereafter, as shown in FIG. 3D, a second silicon oxide film 54 is formed as an interlayer insulation film by CVD. Then, a contact hole is formed in the upper Pt electrode 148. An Al take-out electrode 62 is formed by a DC magnetron sputtering method; this Al take-out electrode 62 is to be coupled to the upper Pt electrode 148 of the ferroelectric capacitor. Next, a contact hole is formed in the first silicon oxide film 52 and the second silicon oxide film 54 overlying the source region 24a, and an Al take-out electrode 64 is formed. Thus, the ferroelectric memory device as shown in FIG. 3D is accomplished.

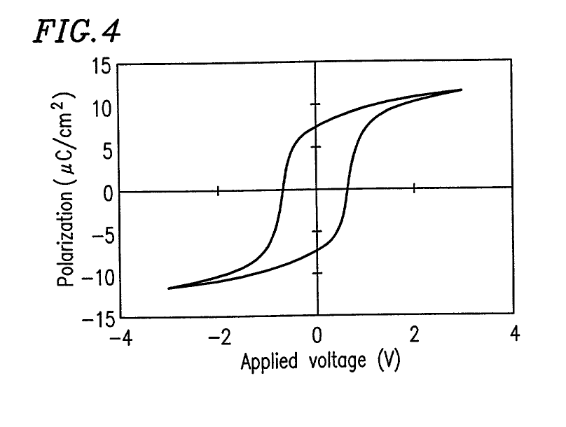

FIG. 4 shows a hysteresis curve which is obtained by applying a voltage having a triangular waveform between the Al take-out electrode 62 from the Pt upper electrode 148 and the Al take-out electrode 64 from the source region 24a which have been formed by the above-described procedure (it is assumed that the applied triangular-waveform voltage has a field intensity of about 150 kV/cm and a frequency of about 75 Hz). The ferroelectric characteristics were as follows: Pr=about 6 μC/cm²; Ec=about 35 kV/cm; a leak current density with a +3 V applied voltage of about 8×10⁻⁸ A/cm²; and an insulation withstand voltage exceeding about 10 V.

As seen from the results shown in FIG. 4, the above-described method provides satisfactory ferroelectric characteristics although the device is employed as a ferroelectric capacitor. Since the symmetry of the hysteresis curve shown in FIG. 4 is maintained, it can be seen that a satisfactory contact is attained between the silicon substrate 10 and the Ir lower electrode 144.

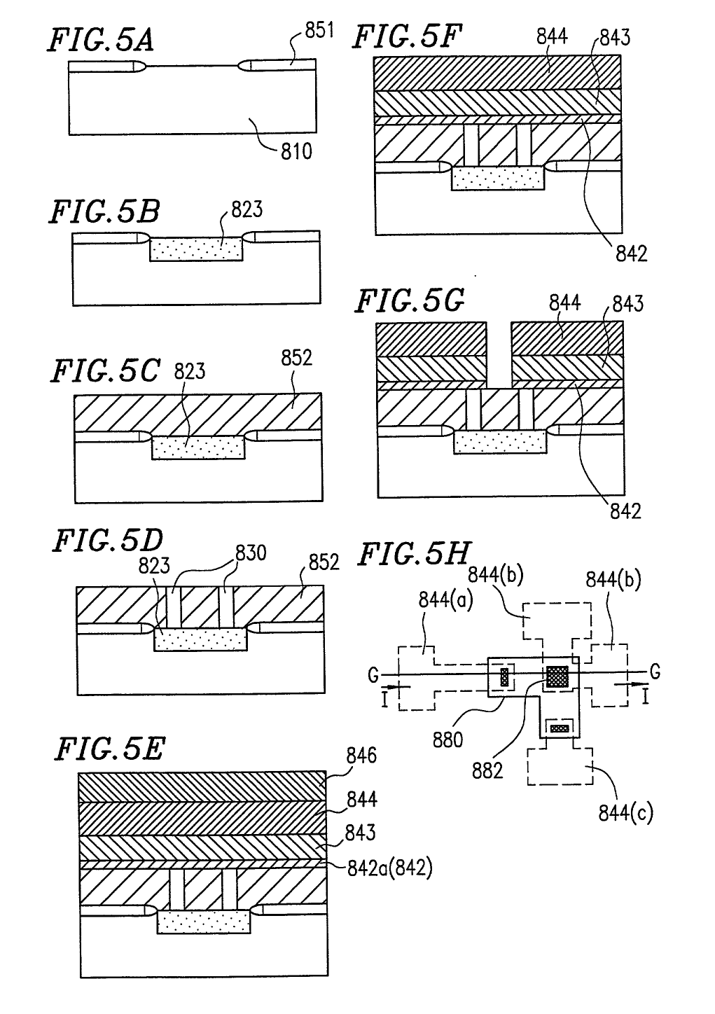

The contact characteristics between the polysilicon conductive plug 30 and the lower electrode 144 and the diffusion barrier film 143 were evaluated by using a Kelvin pattern. Hereinafter, a procedure for preparing a Kelvin pattern will be described with reference to FIGS. 5A to 5H:

First, as shown in FIG. 5A, a LOCOS film 851 is formed on a p-substrate 810. Next, as shown in FIG. 5B, an n-region 823 is formed by injecting phosphorous into the substrate 810. Then, after an interlayer insulation film 852 is formed on the entire substrate surface as shown in FIG. 5C, an n-polysilicon plug 830 is buried for electrical conduction with the n-region 823 as shown in FIG. 5D. After the substrate surface is flattened by CMP, a Ti film 842a, a TaSiN film 843, an Ir film 844, and an SBT film 846 are sequentially formed by the above-described method, as shown in FIG. 5F. Next, the SBT film 846 is subjected to a usual anneal process for crystallization. As a result of performing these steps, the Ti film 842a reacts with the polysilicon of the n-polysilicon plug 830 so as to be converted into a Ti silicide layer 842. Thereafter, as shown in FIG. 5F, the SBT film 846 is removed through dry etching. Next, as shown in FIG. 5G, a hole is formed through the Ti silicide layer 842, the TaSiN film 843, and the Ir film 844 so as to reach the interlayer insulation film 852. Thus, a Kelvin pattern has been produced.

FIG. 5H is a plan view of the structure shown in FIG. 5G. An n-implanted region 880 shown in FIG. 5H for electrically coupling the discrete sections 844(a) to 844(c) of the Ir film 844 is connected to the respective sections 844(a) to 844(c) via a contact section 882. By using this Kelvin pattern, a constant current is allowed to flow from the Ir electrode pad 844(a) to the pad 844(b), and a decrease in the voltage at the contact section 882 is measured between the Ir electrode pad 844(b) and the pad 844(c). Since the wiring resistance is completely negligible, it is possible to measure only the resistance component at the contact section 882.

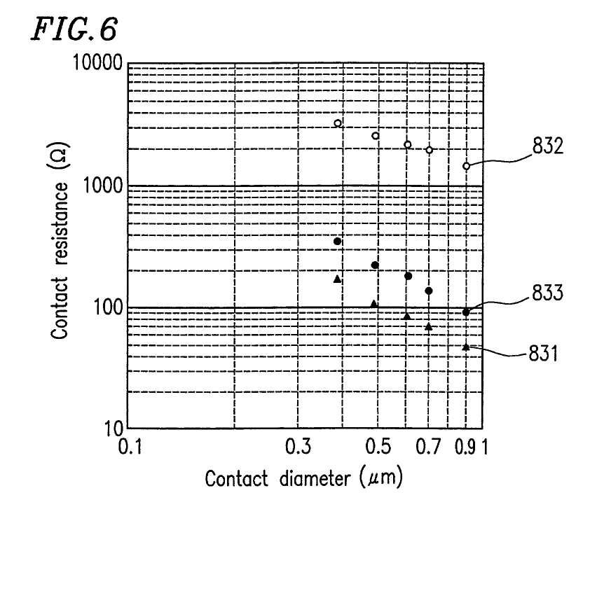

FIG. 6 illustrates the contact diameter dependency of the contact resistance which has been measured by using a Kelvin pattern as described above. In FIG. 6, data 831 represents a resistance value obtained in a structure incorporating the Ti silicide layer 842 of the invention; data 832 represents a resistance value obtained in a structure not incorporating the Ti silicide layer 842; and data 833 represents a resistance value which is obtained prior to an anneal crystallization process in a structure not incorporating the Ti silicide layer 842. Specifically, the data 833 is based on a Kelvin pattern which is prepared by omitting the step of forming an SBT film 846 and anneal crystallization between the step of FIG. 5E (formation of the Ir electrode 844) and the step of FIG. 5G.

As seen from FIG. 6, in accordance with the structure not incorporating a Ti silicide layer 842 (data 832), the contact resistance value obtained with a 0.6 μm contact diameter is increased about ten-fold after the anneal crystallization process from the value before the anneal. On the other hand, in accordance with the structure according to the present invention (data 831), the contact resistance value obtained with a 0.6 μm contact diameter is maintained at as low as about 80 Ω.

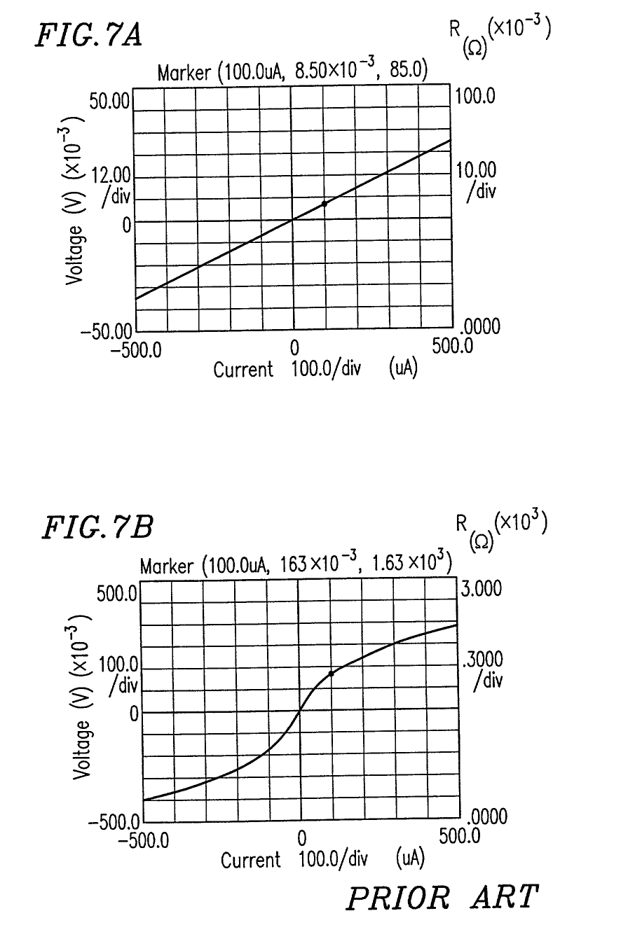

The current-voltage characteristics of the respective structures are shown in FIGS. 7A and 7B. As shown in FIG. 7B, the structure without a Ti silicide layer 842 shows a non-linear curve in the vicinity of 0 V, indicative of changing resistance. On the other hand, as shown in FIG. 7A, the structure according to the present invention exhibits a linear curve, indicative of constant resistance. Non-linear current-voltage characteristics are likely to cause problems such as unwanted delay during a high-speed operation and/or poor S/N ratios in the ferroelectric memory operation. Thus, the structure according to the present invention substantially completely solves such problems.

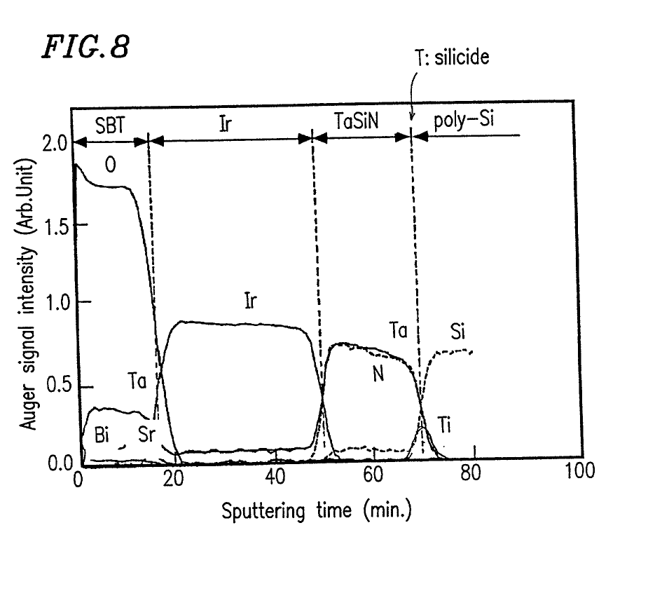

FIG. 8 shows an Auger electron spectroscopy analysis of element concentration, with respect to the depth direction of a device structure of the present invention incorporating a silicide layer, a diffusion barrier, a lower electrode, and an SBT film. The anneal crystallization for the SBT film was performed so that each layer received a 60-minute process in a pure oxygen atmosphere which was maintained at about 675° C., the process being repeated four times. As shown in FIG. 8, mutual diffusion fusion is observed neither between the Ir film and the TaₓSi₁₋ₓN_{y} nor between the TaₓSi₁₋ₓN_{y} and the polysilicon after the anneal crystallization process. Thus, it has been indicated that the Ir film functions as a diffusion barrier film. It can also be seen that the TaₓSi₁₋ₓN_{y} film functions satisfactorily as a barrier film against mutual diffusion of Ir and polysilicon. None of the aforementioned mutual diffusion was observed in a cross-sectional SEM observation, either.

### EXAMPLE 2

A method for producing a ferroelectric memory device according to Example 2 of the present invention will be described.

In Example 1, a metal silicide is formed by first forming a metal flm (Ti film) and a diffusion barrier film (TaₓSi₁₋ₓN_{y} film) on a polysilicon plug, and then performing a heat treatment in a pure nitrogen atmosphere. In the present example, a metal film (Ti film) formed on a polysilicon plug is subjected to a heat treatment for silicidation before a diffusion barrier film is formed. Hereinafter, a method for producing a ferroelectric memory device according to the present example will be described with reference to FIGS. 3A to 3D, which have previously been described in relation to Example 1.

First, as shown in FIG. 3A, a LOCOS film 51 (thickness: about 50 nm) is formed on the surface of a silicon substrate 10 so as to form a device separation region. Then, by using a known method, a selection transistor is formed having a gate electrode 22, source/drain regions 24a and 24b. Thereafter, a first silicon oxide film 52 is formed by CVD as an interlayer insulation film with a thickness of about 500 nm. Then, a contact hole 30a having a diameter of about 0.6 μm is formed.

Next, as shown in FIG. 3B, polysilicon is buried in the contact hole 30a by CVD, and thereafter the surface of the polysilicon is flattened by a CMP method, thereby forming the polysilicon conductive plug 30. Next, the surface of the polysilicon is subjected to a wet process with hydrofluoric acid in order to prevent any spontaneous oxidation films from being formed on the polysilicon, as a pretreatment before forming a Ti film on the polysilicon conductive plug 30.

Thereafter, a Ti film 142a is formed on the polysilicon conductive plug 30 and the first silicon oxide film 52 by DC magnetron sputtering so as to have a thickness of about 1 to about 30 nm (preferably about 5 nm to about 25 nm).

Thereafter, a rapid thermal annealing (RTA) process is performed in a pure nitrogen atmosphere at about 500° C. to about 950° C. for about 5 to about 120 seconds (this process is preferably performed at about 850° C. for about 10 seconds). If the RTA process temperature is less than about 500° C., it becomes difficult to ensure sufficient formation of silicide. On the other hand, performing a heat treatment above about 950° C. may exert undesirable effects on the CMOS's (complementary metal oxide semiconductors) in the integrated circuit. As a result of this process, the polysilicon and the Ti film 242a react with each other so that a Ti silicide layer 142 (thickness: about 2 to about 60 nm) is formed.

Thereafter, a TaₓSi₁₋ₓN_{y} diffusion barrier film 143 (where 0.2≦x≦1 and 0≦y≦1) is formed on the Ti film 142a so as to have a thickness of about 50 to about 150 nm (preferably about 80 to about 120 nm) by a DC reactive magnetron sputtering method. After the TaₓSi₁₋ₓN_{y} film 143 is formed, a heat treatment is conducted in a pure nitrogen atmosphere at about 500° C. to about 800° C. (preferably about 600° C.) for 1 hour. The resistivity of the TaₓSi₁₋ₓN_{y} film 143 after a heat treatment in a pure nitrogen atmosphere was measured to be in the range of about 100 to about 2000 μΩ cm.

The conditions for forming the Ti film 142 and the TaₓSi₁₋ₓN_{y} diffusion barrier film 143 are identical with those employed in Example 1. The steps subsequent to the formation of the diffusion barrier film 143 (i.e., steps corresponding to FIGS. 3C and 3D) are identical with those employed in Example 1, and the description thereof is omitted.

A contact resistance evaluation was performed by using a Kelvin pattern in a similar manner to that described in Example 1. As a result, it was confirmed that the contact resistance value obtained with a 0.6 μm contact diameter according to the present invention is maintained at as low as about 80 Ω. The current-voltage characteristics of the structure according to the present invention also exhibited a linear curve, indicative of constant resistance. After the SBT film is formed according to the present invention, no hillocks or peeling was observed in the lower electrode.

Although a Ti film is employed as a metal film forming the silicide layer in Examples 1 and 2, similar effects can also be attained by employing a metal element selected from IV-A group elements (Zr and Hf), V-A group elements (V, Nb, and Ta), VI-A group elements (Cr, Mo, and W), and VIII group elements (Ru, Os, Co, Rh, Ir, Ni, Pd and Pt), instead of Ti.

### EXAMPLE 3

A method for producing a ferroelectric memory device according to Example 3 of the present invention will be described.

In Examples 1 and 2, a metal film (Ti film) is formed on a polysilicon plug, and the metal film is subjected to a heat treatment to form a metal silicide layer. In the present example, a metal silicide layer is directly formed on a polysilicon plug.

First, the structure shown in FIG. 3A is formed by a method similar to those described in Examples 1 and 2, and a polysilicon plug 30 is further formed.

Next, a layer 142b containing Ti and Si is formed on the polysilicon film so as to have a thickness of about 1 to about 30 nm (preferably about 5 to about 25 nm) by a DC magnetron sputtering method. The film formation conditions for forming the layer 142b according to the present example are as follows: a mixture target whose Ti/Si molar ratio is about 10/3 is used; the substrate temperature is about 500° C.; a sputter power of about 2 kW is used; a sputter gas pressure of about 0.7 Pa is used; and an Ar sputter gas is used. Since the substrate temperature is low, the layer 142b has not been converted into a silicide film.

Thereafter, a TaₓSi₁₋ₓN_{y} diffusion barrier film 143 (where 0.2≦x≦1 and 0≦y≦1) is formed on the layer 142b containing Ti and Si so as to have a thickness of about 50 to about 150 nm (preferably about 80 to about 120 nm) by a DC reactive magnetron sputtering method. Thereafter, a heat treatment is conducted in a pure nitrogen atmosphere at about 500° C. to about 800° C. (preferably about 600° C.) for 1 hour. This heat treatment causes the layer 142b containing Ti and Si to react with the polysilicion so as to be converted into a silicide layer 142 (thickness: about 2 to about 60 nm). The resistivity of the TaₓSi₁₋ₓN_{y} film 143 after a heat treatment in a pure nitrogen atmosphere was measured to be in the range of about 100 to about 2000 μΩ cm.

The steps subsequent to the formation of the diffusion barrier film 143 (i.e., steps corresponding to FIGS. 3C and 3D) are identical with those employed in Example 1, and the description thereof is omitted.

Although the conductive plug 30 illustrated in the present example is formed of polysilicon, it may alternatively be formed of tungsten.

A contact resistance evaluation was performed by using a Kelvin pattern in a similar manner to that described in Example 1. As a result, it was confirmed that the contact resistance value obtained with a 0.6 μm contact diameter according to the present invention is maintained at as low as about 120 Ω. The current-voltage characteristics of the structure according to the present invention also exhibited a linear curve, indicative of constant resistance. After the SBT film is formed according to the present invention, no hillocks or peeling was observed in the lower electrode.

### EXAMPLE 4

A method for producing a ferroelectric memory device according to Example 4 of the present invention will be described.

In Example 3, a layer 142b containing Ti and Si is formed on a polysilicon plug, and a diffusion barrier film 143 is formed, and thereafter the metal film is subjected to a heat treatment to convert the layer 142b into a silicide layer 142. In the present example, a Ti silicide film 142 is first formed on polysilicon, and thereafter a diffusion film 143 is formed.

First, the structure shown in FIG. 3A is formed by a method similar to those described in Examples 1 and 2, and a polysilicon plug 30 is further formed.

Next, as shown in FIG. 3B, a layer 142b containing Ti and Si is formed on the polysilicon film so as to have a thickness of about 1 to about 30 nm (preferably about 5 to about 25 nm) by a DC magnetron sputtering method. The film formation conditions for forming the layer 142b according to the present example are as follows: a mixture target whose Ti/Si molar ratio is about 10/3 is used; the substrate temperature is about 500° C.; a sputter power of about 2 kW is used; a sputter gas pressure of about 0.7 Pa is used; and an Ar sputter gas is used.

Thereafter, an RTA process is performed in a pure nitrogen atmosphere at about 500° C. to about 950° C. for about 5 to about 120 seconds (this process is preferably performed at about 850° C. for about 10 seconds). As a result of this process, the layer 142b containing Ti and Si reacts with the polysilicon so as to be converted into a Ti silicide layer 142.

Thereafter, a TaₓSi₁₋ₓN_{y} diffusion barrier film 143 (where 0.2≦x≦1 and 0≦y≦1) is formed on the Ti silicide layer 142 so as to have a thickness of about 50 to about 150 nm (preferably about 80 to about 120 nm) by a DC reactive magnetron sputtering method. Thereafter, a heat treatment is conducted in a pure nitrogen atmosphere at about 500° C. to about 800° C. (preferably about 600° C.) for 1 hour. The resistivity of the TaₓSi₁₋ₓN_{y} film 143 after a heat treatment in a pure nitrogen atmosphere was measured to be in the range of about 100 to about 2000 μΩ cm.

The steps subsequent to the formation of the diffusion barrier film 143 (i.e., steps corresponding to FIGS. 3C and 3D) are identical with those employed in Example 1, and the description thereof is omitted.

A contact resistance evaluation was performed by using a Kelvin pattern in a similar manner to that described in Example 1. As a result, it was confirmed that the contact resistance value obtained with a 0.6 μm contact diameter according to the present invention is maintained at as low as about 130 Ω. The current-voltage characteristics of the structure according to the present invention also exhibited a linear curve, indicative of constant resistance. After the SBT film is formed according to the present invention, no hillocks or peeling were observed in the lower electrode.

Although a Ti film is employed as a metal film forming the silicide layer 142 in Examples 3 and 4, similar effects can also be attained by employing a metal element selected from IV-A group elements (Zr and Hf), V-A group elements (V, Nb, and Ta), VI-A group elements (Cr, Mo, and W), and VIII group elements (Ru, Os, Co, Rh, Ir, Ni, Pd and Pt), instead of Ti.

### EXAMPLE 5

A method for producing a ferroelectric memory device according to Example 5 of the present invention will be described. In the present example, a Ti film and a layer containing Ti and Si are sequentially formed on a polysilicon plug 30, whereupon a TaₓSi₁₋ₓN_{y} diffusion barrier film 143 is formed. Thereafter, a heat treatment is performed in a pure nitrogen atmosphere to form a Ti silicide layer.

First, the structure shown in FIG. 3A is formed by a method similar to those described in Examples 1 and 2, and a polysilicon plug 30 is further formed. Next, the surface of the polysilicon is subjected to a wet process with hydrofluoric acid in order to prevent any spontaneous oxidation films from being formed on the polysilicon, as a pretreatment before forming a Ti film on the polysilicon conductive plug 30.

Thereafter, a Ti film 142a is formed on the polysilicon conductive plug 30 and a first silicon oxide film 52 by DC magnetron sputtering so as to have a thickness of about 1 to about 30 nm (preferably about 5 nm to about 25 nm). Next, a layer containing Ti and Si is formed on the polysilicon film so as to have a thickness of about 1 to about 30 nm (preferably about 5 to about 25 nm) by a DC magnetron sputtering method. The film formation conditions for forming the layer containing Ti and Si according to the present example are as follows: a mixture target whose Ti/Si molar ratio is about 10/3 is used; the substrate temperature is about 500° C.; a sputter power of about 2 kW is used; a sputter gas pressure of about 0.7 Pa is used; and an Ar sputter gas is used. The structure including the Ti film and the Ti/Si-containing layer is referred to as a layer 142c (FIG. 3B).

Thereafter, a TaₓSi₁₋ₓN_{y} diffusion barrier film 143 (where 0.2≦x≦1 and 0≦y≦1) is formed on the layer 142c so as to have a thickness of about 50 to about 150 nm (preferably about 80 to about 120 nm) by a DC reactive magnetron sputtering method.

After the formation of the TaₓSi₁₋ₓN_{y} film 143, a heat treatment is conducted in a pure nitrogen atmosphere at about 500° C. to about 800° C. (preferably about 600° C.) for 1 hour. As a result of this heat treatment, the Ti film within the layer 142c reacts with the underlying polysilicon so as to be converted into a Ti silicide layer. Also, the Ti/Si-containing layer within the layer 142a is converted into a Ti silicide layer. Thus, a Ti silicide layer 142 (having a total thickness of about 2 to about 60 nm) is formed. The resistivity of the TaₓSi₁₋ₓN_{y} film 143 after a heat treatment in a pure nitrogen atmosphere was measured to be in the range of about 100 to about 2000 μΩ cm.

The steps subsequent to the formation of the diffusion barrier film 143 (i.e., steps corresponding to FIGS. 3C and 3D) are identical with those employed in Example 1, and the description thereof is omitted.

A contact resistance evaluation was performed by using a Kelvin pattern in a similar manner to that described in Example 1. As a result, it was confirmed that the contact resistance value obtained with a 0.6 μm contact diameter according to the present invention is maintained at as low as about 130 Ω. The current-voltage characteristics of the structure according to the present invention also exhibited a linear curve, indicative of constant resistance. After the SBT film is formed according to the present invention, no hillocks or peeling were observed in the lower electrode.

Similar effects can also be attained by employing, instead of Ti, any other metal element as exemplified in Examples 1 to 4 as a metal element composing the metal film (illustrated as a Ti film in the present example) and the other layer (illustrated as a layer containing Ti and Si in the present example).

### EXAMPLE 6

A method for producing a ferroelectric memory device according to Example 6 of the present invention will be described. In the present example, a metal silicide layer is formed on a polysilicon plug 30, whereupon a further metal layer is formed.

First, the structure shown in FIG. 3A is formed by a method similar to those described in Examples 1 and 2, and a polysilicon plug 30 is further formed. Next, the surface of the polysilicon is subjected to a wet process with hydrofluoric acid in order to prevent any spontaneous oxidation films from being formed on the polysilicon, as a pretreatment before forming a Ti film on the polysilicon conductive plug 30.

Thereafter, a Ti film 142a is formed on the polysilicon conductive plug 30 and a first silicon oxide film 52 by DC magnetron sputtering so as to have a thickness of about 1 to about 30 nm (preferably about 5 nm to about 25 nm) (FIG. 3B).

Thereafter, an RTA process is performed in a pure nitrogen atmosphere at about 500° C. to about 950° C. for about 5 to about 120 seconds (this process is preferably performed at about 850° C. for about 10 seconds). As a result of this process, the Ti film 142a reacts with the polysilicon so as to be converted into a Ti silicide layer 142. If the RTA process temperature is less than about 500° C., it becomes difficult to ensure sufficient formation of silicide. On the other hand, performing a heat treatment above about 950° C. may exert undesirable effects on the CMOS's in the integrated circuit.

Thereafter, a Ti film (not shown in FIG. 3B) is again formed on the Ti silicide layer 142 so as to have a thickness of about 1 to 30 nm (preferably about 5 to about 25 nm).

Thereafter, a TaₓSi₁₋ₓN_{y} diffusion barrier film 143 (where 0.2≦x≦1 and 0≦y≦1) is formed on the Ti film so as to have a thickness of about 50 to about 150 nm (preferably about 80 to about 120 nm) by a DC reactive magnetron sputtering method. After the formation of the TaₓSi₁₋ₓN_{y} film 143, a heat treatment is conducted in a pure nitrogen atmosphere at about 500° C. to about 800° C. (preferably about 600° C.) for 1 hour. Even after this heat treatment, the Ti film formed on the Ti silicide layer 142 is not converted into a Ti silicide layer, but remains as a metal film between the Ti silicide layer 142 and the diffusion barrier film 143. The resistivity of the TaₓSi₁₋ₓN_{y} film after a heat treatment in a pure nitrogen atmosphere was measured to be in the range of about 100 to about 2000 μΩ cm.

The steps subsequent to the formation of the diffusion barrier film 143 (i.e., steps corresponding to FIGS. 3C and 3D) are identical with those employed in Example 1, and the description thereof is omitted.

According to the present example, the contact resistance is further reduced due to the presence of the Ti film between the Ti silicide layer 142 and the diffusion barrier film 143.

A contact resistance evaluation was performed by using a Kelvin pattern in a similar manner to that described in Example 1. As a result, it was confirmed that the contact resistance value obtained with a 0.6 μm contact diameter according to the present invention is maintained at as low as about 80 Ω. The current-voltage characteristics of the structure according to the present invention also exhibited a linear curve, indicative of constant resistance. After the SBT film is formed according to the present invention, no hillocks or peeling was observed in the lower electrode.

Similar effects can also be attained by employing, instead of Ti, any other metal element as exemplified in Examples 1 to 4 as a metal element composing the silicide layer 142 and the metal film upon the silicide layer 142.

According to the present invention, the following effects are provided.

Since a metal silicide layer is provided between a conductive plug and a diffusion barrier film, any increase in the resistance after the annealing for ferroelectric crystallization can be prevented. As a result, problems such as unwanted delay during a high-speed operation and/or poor S/N ratios in the ferroelectric memory operation can be prevented.

By combining a diffusion barrier film having a defined composition and a lower electrode having a defined material, it becomes possible to provide an electrode/diffusion barrier structure having sufficient stability (i.e., substantially free of hillocks and peeling).

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A ferroelectric memory device comprising:
a capacitor having an upper electrode, a ferroelectric film, and a lower electrode;
a conductive plug disposed under the lower electrode for electrically connecting the lower electrode to a selection transistor; and
a diffusion barrier film formed between the conductive plug and the lower electrode for preventing a diffusion reaction between the conductive plug and the lower electrode,
wherein a silicide layer is formed between the conductive plug and the diffusion barrier film, the silicide layer comprising a first metal element.

2. A ferroelectric memory device according to claim 1, wherein the first metal element is selected from IV-A group elements (Ti, Zr, and Hf), V-A group elements (V, Nb, and Ta), VI-A group elements (Cr, Mo, and W), and VIII group elements (Ru, Os, Co, Rh, Ir, Ni, Pd and Pt).

3. A ferroelectric memory device according to claim 1,
wherein the diffusion barrier film comprises one of AₓSi₁₋ₓN_{y}, AₓAl₁₋ₓN_{y}, and BN₂ (where 0.2≦x<1; 0≦y≦1; 0 ≦z<1), wherein
A is an element which is selected from a group including Ti, Zr, Hf, V, Nb, Ta, Cr, Mo, W, Ru, Os, Co, Rh, Ir, Ni, Pd, and Pt; and
B is an element which is selected from a group including Zr, Hf, V, Nb, Ta, Cr, Mo, W, Ru, Os, Co, Rh, Ir, Ni, Pd, and Pt.

4. A ferroelectric memory device according to claim 1, wherein the lower electrode comprises at least one of an Ir film and a multilayer film including an Ir layer and an IrO₂ layer.

5. A ferroelectric memory device according to claim 1, wherein the silicide layer has a thickness of about 2 to about 60 nm.

6. A ferroelectric memory device according to claim 1, wherein the conductive plug comprises polysilicon.

7. A method for producing a ferroelectric memory device comprising:
a capacitor having an upper electrode, a ferroelectric film, and a lower electrode;
a conductive plug disposed under the lower electrode for electrically coupling the lower electrode to a selection transistor; and
a diffusion barrier film formed between the conductive plug and the lower electrode for preventing a diffusion reaction between the conductive plug and the lower electrode,
wherein the method comprises a step of forming a silicide layer between the conductive plug and the diffusion barrier film, the silicide layer comprising a first metal element.

8. A method according to claim 7, wherein the first metal element is selected from IV-A group elements (Ti, Zr, and Hf), V-A group elements (V, Nb, and Ta), VI-A group elements (Cr, Mo, and W), and VIII group elements (Ru, Os, Co, Rh, Ir, Ni, Pd and Pt).

9. A method according to claim 7, wherein the conductive plug comprises silicon, and
wherein the step of forming the silicide layer comprises:
forming a metal layer on the conductive plug, the metal layer comprising the first metal element; and
performing a heat treatment in an inert gas atmosphere to convert the metal layer into the silicide layer.

10. A method according to claim 7,
wherein the step of forming the silicide layer comprises:
forming a first layer on the conductive plug, the first layer comprising the first metal element and Si; and
performing a heat treatment in an inert gas atmosphere to convert the first layer into the silicide layer.

11. A method according to claim 7, wherein the conductive plug comprises silicon, and
wherein the step of forming the silicide layer comprises:
forming a metal layer on the conductive plug, the metal layer comprising the first metal element;
forming a first layer on the metal layer, the first layer comprising the first metal element and Si; and
performing a heat treatment in an inert gas atmosphere to convert the metal layer and the first layer into the silicide layer.

12. A method according to claim 7, wherein the conductive plug comprises silicon, and
wherein the step of forming the silicide layer comprises:
forming a first metal layer on the conductive plug, the first metal layer comprising the first metal element;
performing a heat treatment in an inert gas atmosphere to convert the first metal layer into the silicide layer; and
forming a second metal layer on the silicide layer, the second metal layer comprising the first metal element.

13. A method according to claim 9, wherein the inert gas comprises nitrogen gas.

14. A method according to claim 9, wherein the heat treatment is performed before forming the diffusion barrier film, the heat treatment being performed at a temperature ranging from about 500° C. to about 950° C.

15. A method according to claim 9, wherein the heat treatment is performed after forming the diffusion barrier film, the heat treatment being performed at a temperature ranging from about 500° C. to about 800° C.

16. A method according to claim 7,
wherein the diffusion barrier film comprises one of AₓSi₁₋ₓN_{y}, AₓAl₁₋ₓN_{y}, and BN₂ (where 0.2≦x<1, 0≦y≦1; 0 ≦z<1 ), wherein
A is an element which is selected from a group including Ti, Zr, Hf, V, Nb, Ta, Cr, Mo, W, Ru, Os, Co, Rh, Ir, Ni, Pd, and Pt; and
B is an element which is selected from a group including Zr, Hf, V, Nb, Ta, Cr, Mo, W, Ru, Os, Co, Rh, Ir, Ni, Pd, and Pt.
